(19) United States
(12) Patent Application Publication
(10) Pub. No.: US 2026/0107769 A1
(43) Pub. Date: Apr. 16, 2026

(54) SEMICONDUCTOR PACKAGE AND METHOD

(71) Applicant: Taiwan Semiconductor Manufacturing Co., Ltd., Hsinchu (TW)

(72) Inventors: Yu-Han Wang, Hsinchu (TW); Yen-Ming Chen, Hsinchu (TW); Ming-Tsu Chung, Hsinchu (TW); Yung-Chi Lin, Su-Lin City (TW)

(21) Appl. No.: 19/080,131

(22) Filed: Mar. 14, 2025

Related U.S. Application Data
(60) Provisional application No. 63/706,813, filed on Oct. 14, 2024.

(51) Int. Cl. H01L 23/367; H01L 21/48; H01L 23/00; H01L 23/053; H01L 23/373; H01L 25/065; H01L 25/18; H10B 80/00

(52) U.S. Cl. CPC H10W 40/226; H10W 40/253; H10W 70/027; H10W 76/15; H10B 80/00; H10W 72/019; H10W 74/15; H10W 80/312; H10W 90/00; H10W 90/20; H10W 90/288; H10W 90/724; H10W 90/734; H10W 90/792

(57) ABSTRACT

A semiconductor package and the method of forming the same are provided. The semiconductor package may include a package substrate and a first package component over the package substrate. The first package component may include a first semiconductor die and a heat dissipation substrate over the first semiconductor die. The heat dissipation substrate may comprise a base portion and a first coating portion on a first surface of the base portion. The first coating portion may be between the first semiconductor die and the base portion. The base portion may comprise a first material with a first thermal conductivity and the first coating portion may comprise a second material different from the first material. The second material may have a second thermal conductivity smaller than the first thermal conductivity.

### PRIORITY CLAIM AND CROSS-REFERENCE

This application claims the benefit of U.S. Provisional Application No. 63/706,813, filed on Oct. 14, 2024, which application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a trend for smaller and more creative packaging techniques of semiconductor dies has emerged. An example of such packaging systems is Package-on-Package (PoP) technology. In a PoP device, a top semiconductor package is stacked on top of a bottom semiconductor package to provide a high level of integration and component density. PoP technology generally enables production of semiconductor devices with enhanced functionalities and small footprints on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 and 2A illustrate cross-sectional views of intermediate steps during the manufacturing of a carrier substrate, in accordance with some embodiments.

FIG. 2B illustrates a cross-sectional view of a carrier substrate, in accordance with some embodiments.

FIGS. 3, 4, 5, 6, 7, 8, 9, 10, 11, 12, 13, 14, and 15A illustrate cross-sectional views of intermediate steps during the manufacturing of a semiconductor package using the carrier substrate, in accordance with some embodiments.

FIG. 15B illustrates a cross-sectional view a semiconductor package using the carrier substrate, in accordance with some embodiments.

FIGS. 16, 17, 18, and 19 illustrate cross-sectional views of intermediate steps during the manufacturing of a semiconductor package using the carrier substrate, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor package and the method of forming the same are provided. In accordance with some embodiments, the semiconductor package may comprise semiconductor dies that may generate heat during operation of the semiconductor package. The semiconductor dies may be bonded over a package substrate and a lid may be attached to the package substrate. A carrier substrate may be disposed between the lid and the semiconductor dies. Since the carrier substrate comprises a material with a high thermal conductivity, and have low roughness on top and bottom surfaces, the heat generated by the semiconductor dies may be more effectively transferred to the carrier substrate, and then to the lid, where said heat may be dissipated. As a result, the performance and reliability of the semiconductor package may be improved.

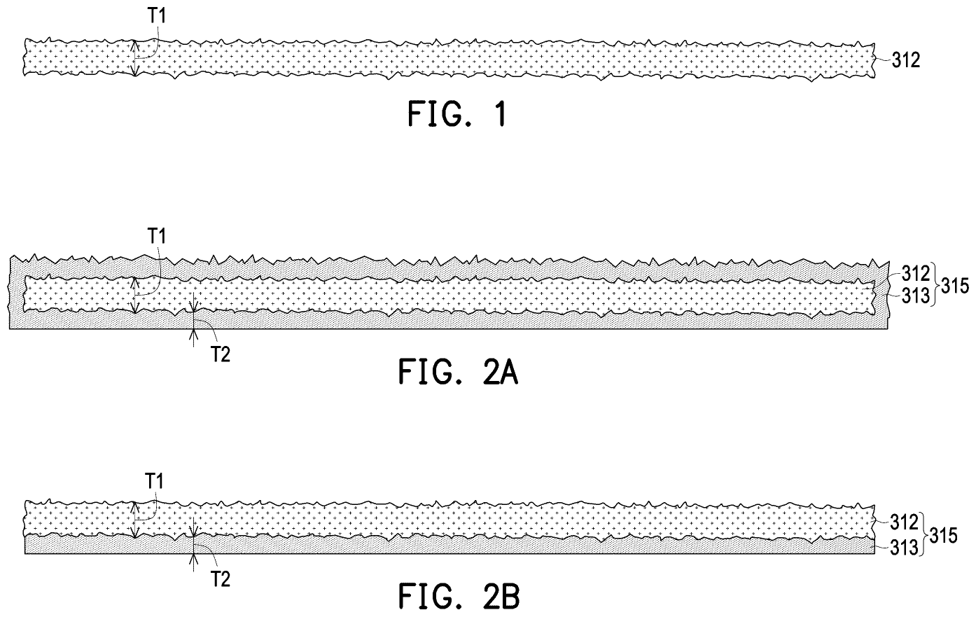

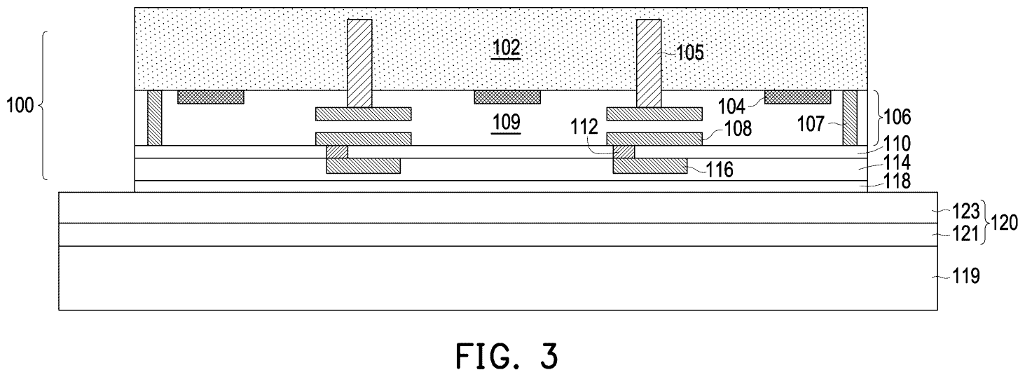

FIGS. 1 and 2A illustrate cross-sectional views of intermediate steps during the manufacturing of a carrier substrate, in accordance with some embodiments. In FIG. 1, a wafer 312 is provided. The material of the wafer 312 may be polycrystalline and have a first thermal conductivity greater than about 170 W/mK, which may be a high thermal conductivity with advantages as described in greater detail below. In some embodiments, the wafer 312 comprises a semiconductor material, such as silicon carbide or the like, and the first thermal conductivity is in a range from about 230 W/mK to about 500 W/mK. In some embodiments, the wafer 312 comprises a dielectric material, such as aluminum nitride or the like, and the first thermal conductivity is in a range from about 170 W/mK to about 250 W/mK. The wafer 312 may be formed by a suitable process, such as chemical vapor deposition (CVD), sintering, or the like. The wafer 312 may have a thickness T1 in a range from about 620 um to about 800 um. Surfaces of the wafer 312, including a top surface and a bottom surface, may have a first roughness (e.g., an average roughness (Ra)) in a range from about 0.3 nm to about 30 nm. The wafer 312 may have a diameter about 12 inches.

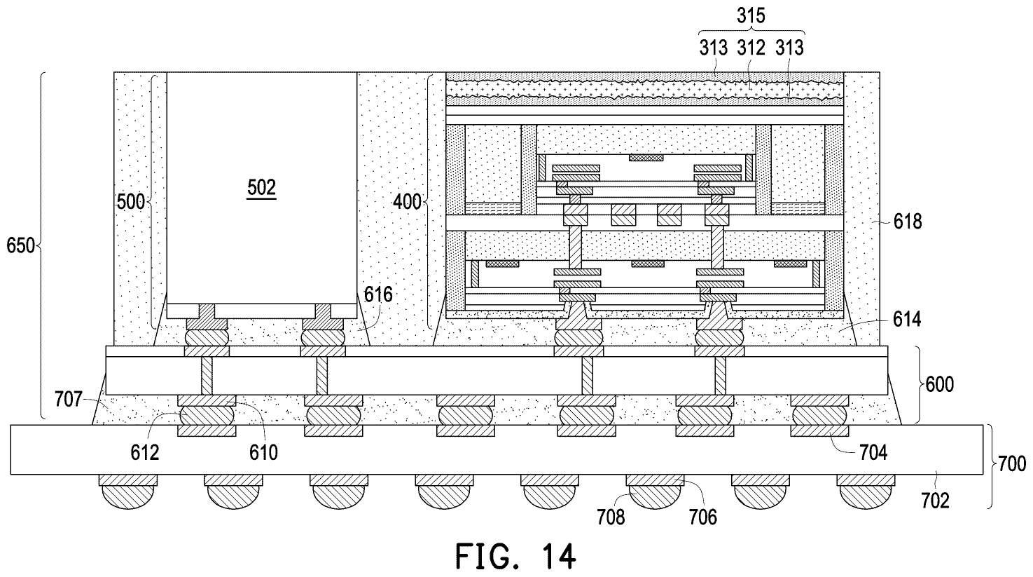

In FIG. 2A, a coating layer 313 is formed on the surfaces of the wafer 312 and a bottom surface (the surface facing downward in FIG. 2A) of the coating layer 313 is planarized. A top surface (the surface facing upward in FIG. 2A) of the coating layer 313 may be planarized in a subsequent process described in greater detail later, such as in FIG. 13. The coating layer 313 may enclose (e.g., wrap around) the wafer 312. The coating layer 313 may be on the top surface, the bottom surface, and sidewalls of the wafer 312. The material of the coating layer 313 may be polycrystalline and have a second thermal conductivity smaller than the first thermal conductivity of the material of the wafer 312. In some embodiments, the coating layer 313 comprises a semiconductor material, such as silicon or the like, and the second thermal conductivity is in a range from about 5 W/mK to about 170 W/mK. In some embodiments, the coating layer 313 comprises a dielectric material, such as silicon nitride, aluminum oxide, or the like, and the second thermal conductivity is in a range from about 1 W/mK to about 50 W/mK. The coating layer 313 may be formed by a suitable process, such as CVD, plasma-enhanced CVD (PECVD), or the like.

The bottom surface of the coating layer 313 may be planarized by a chemical-mechanical polish (CMP) process or the like. After the planarization process, the bottom surface of the coating layer 313 may have a second roughness (e.g., an average roughness (Ra)) smaller than about 0.3 nm, and a bottom portion of the coating layer 313 adjacent the bottom surface may have a thickness T2 in a range from about 1 nm to about 1 um. The second roughness may be smaller than the first roughness, and the thickness T2 may be smaller than the thickness T1. A ratio of the thickness T2 to the thickness T1 may be smaller than 0.0002. The wafer 312 and the coating layer 313 may be collectively referred to as a second carrier substrate 315, wherein the wafer 312 may be referred to as a base portion of the second carrier substrate 315 and the coating layer 313 may be referred to as a coating portion of the second carrier substrate 315.

The second carrier substrate 315 may be used to manufacture a semiconductor package where the second carrier substrate 315 may be bonded to a structure comprising heat-generating devices as described in greater detail below. Since the bottom surface of the coating layer 313 has a low roughness as described above, the bonding between the second carrier substrate 315 and said structure may be more effective. When the bottom surface of the coating layer 313 has a surface roughness less than 0.3 nm, improved bonding strength between the second carrier substrate 315 and said structure may be achieved. Due to the high thermal conductivity of the material of the wafer 312 (e.g., greater than 170 W/mK) as described above and the improved bonding strength between the second carrier substrate 315 and said structure, the second carrier substrate 315 may be more effective in dissipating heat generated in said structure as described in greater detail below. A small ratio of the thickness T2 to the thickness T1 (e.g., smaller than 0.0002) may improve the heat dissipation capability of the second carrier substrate 315, since the second thermal conductivity of the material of the coating layer 313 may be smaller than the first thermal conductivity of the material of the wafer 312.

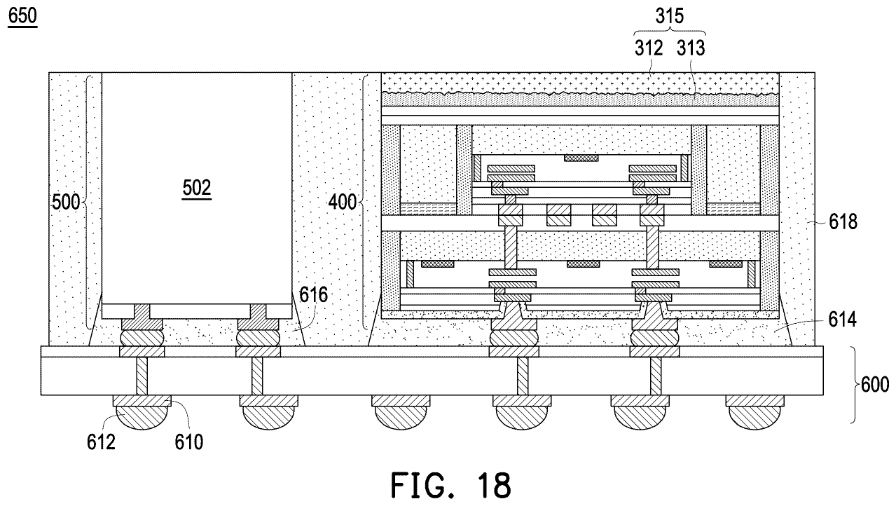

FIG. 2B shows a second carrier substrate 315 in accordance with some alternative embodiments similar to the embodiments of the second carrier substrate 315 shown in FIG. 2A, wherein like numerals refer to like features formed of like materials and by like processes. In FIG. 2B, the coating layer 313 is selectively formed on the bottom surface (the surface facing downward in FIG. 2B) of the wafer 312, by a suitable process, such as CVD, PECVD, or the like, while other surfaces of the wafer 312 remain exposed after the coating layer 313 is formed. The material of the wafer 312 may have the first thermal conductivity and the material of the coating layer 313 may have the second thermal conductivity smaller than the first thermal conductivity. The surfaces of the wafer 312 may have the first roughness. The bottom surface (the surface facing downward in FIG. 2B) of the coating layer 313 may be planarized and have the second roughness smaller than the first roughness. A top surface (the surface facing upward in FIG. 2B) of the wafer 312 may be planarized in a subsequent process described in greater detail later, such as in FIG. 18.

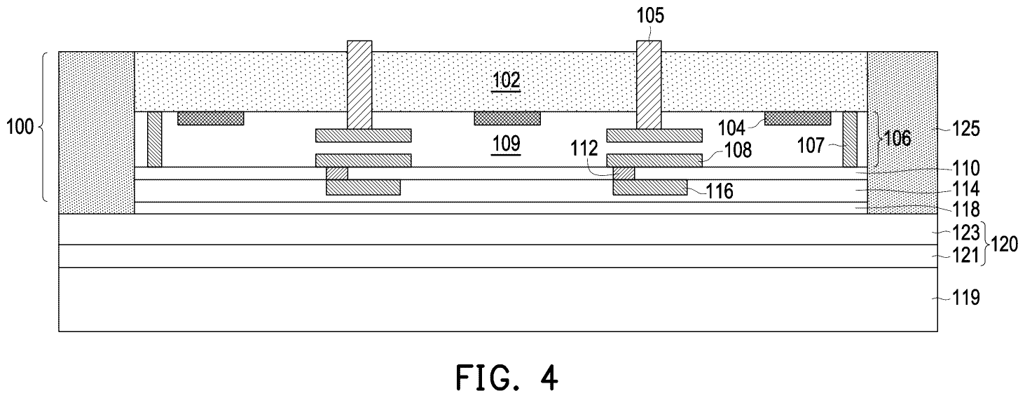

FIGS. 3, 4, 5, 6, 7, 8, 9, 10, 11, 12, 13, 14, and 15A illustrate cross-sectional views of intermediate steps during the manufacturing of a semiconductor package using the carrier substrate, in accordance with some embodiments. Referring to FIG. 3, a bottom semiconductor die 100 is attached to a first carrier substrate 119. The bottom semiconductor die 100 may be a bare semiconductor die (e.g., unpackaged semiconductor die) that is formed as part of a larger wafer. For example, the bottom semiconductor die 100 may be a logic die (e.g., application processor (AP), central processing unit (CPU), microcontroller, etc.), a memory die (e.g., dynamic random access memory (DRAM) die, hybrid memory cube (HBC), a static random access memory (SRAM) die, a wide input/output (wide IO) memory die, a magnetoresistive random access memory (mRAM) die, a resistive random access memory (rRAM) die, etc.), a power management die (e.g., power management integrated circuit (PMIC) dies), a radio frequency (RF) die, a sensor die, a micro-electro-mechanical-system (MEMS) die, a signal processing die (e.g., digital signal processing (DSP) die), a front-end die (e.g., analog front-end (AFE) die), a biomedical die, or the like. The bottom semiconductor die 100 may be a package comprising one or more bare semiconductor dies.

The bottom semiconductor die 100 may be processed according to applicable manufacturing processes to form integrated circuits in the bottom semiconductor die 100. The bottom semiconductor die 100 may be formed as part of a larger wafer with other semiconductor dies and subsequently singulated from the wafer. The bottom semiconductor die 100 may include a substrate 102, such as silicon, doped or undoped, or an active layer of a semiconductor-on-insulator (SOI) substrate. The substrate 102 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

Electrical devices 104 (i.e., active and/or passive devices), such as transistors, diodes, capacitors, resistors, and the like, may be formed in and/or on the substrate 102. The electrical devices 104 may generate relatively high levels of heat during operation, thereby creating thermal hotspots. The electrical devices 104 may be interconnected by an interconnect structure 106 comprising metallization patterns 108 in one or more dielectric layers 109 on the substrate 102. The interconnect structure 106 electrically connect the electrical devices 104 on the substrate 102 to form one or more integrated circuits. The metallization patterns 108 may comprise conductive material such as, copper, aluminum, or the like. The one or more dielectric layers 109 may comprise low-k dielectric materials, such as silicon oxide or the like. Seal ring 107 may be formed in the interconnect structure 106 and may extend through the one or more dielectric layers 109 of the interconnect structure 106. The seal ring 107 may encircle the electrical devices 104 in a top-down view. In some embodiments, the seal ring 107 is formed of a same material and the metallization patterns 108.

The bottom semiconductor die 100 may further include through vias 105, which may be electrically connected to the metallization patterns 108 in the interconnect structure 106. The through vias 105 may comprise a conductive material such as, copper, aluminum, or the like, and may extend from the interconnect structure 106 into the substrate 102. One or more insulating barrier layers (not shown) may be formed around at least portions of the through vias 105 in the substrates 102. In subsequent processing steps, the substrate 102 may be thinned to expose the through vias 105. After being exposed, the through vias 105 may provide electrical connection from a back side of the substrate 102 to a front side of the substrate 102. In some embodiments, the back side of the substrate 102 may refer to a side of the substrate 102 opposite to the electrical devices 104 and the interconnect structure 106 while the front side of the substrate 102 may refer to a side of the substrate 102 on which the electrical devices 104 and the interconnect structure 106 are disposed.

The bottom semiconductor die 100 may further comprise one or more passivation layers 110 on the interconnect structure 106 and conductive vias 112 extending through the one or more passivation layers 110. The conductive vias 112 may be in electrical connection with the metallization patterns 108. The one or more passivation layers 110 may comprise dielectric materials, such as silicon nitride, silicon oxycarbide, or the like. The conductive vias 112 may comprise a conductive material such as, copper, aluminum, or the like. A dielectric layer 114 is disposed on the one or more passivation layers 110 and contact pads 116 are embedded in the dielectric layer 114. The contact pads 116 may be in electrical connection with the conductive vias 112. In subsequent processing steps, openings may be formed in the dielectric layer 114 to expose the contact pads 116. After being exposed, the contact pads 116 provide electrical connection to the electrical devices 104 and the interconnect structure 106. The dielectric layer 114 may comprise a dielectric material, such as silicon oxide, silicon nitride, or the like. The contact pads 116 may comprise a conductive material such as, copper, aluminum, or the like. A dielectric layer 118 is disposed on the dielectric layer 114. The dielectric layer 118 may comprise a dielectric material, such as silicon oxide, silicon oxynitride, or the like.

The first carrier substrate 119 may be a semiconductor carrier, a glass carrier, a ceramic carrier, or the like. The first carrier substrate 119 may be a wafer with a size similar to the second carrier substrate 315. FIG. 3 illustrates one bottom semiconductor die 100 bonded to the first carrier substrate 119 as an example, two or more bottom semiconductor dies 100 may be bonded to the first carrier substrate 119 and processed together during the subsequent manufacturing steps until being singulated into individual semiconductor packages. A bonding layer 120 may be disposed on the first carrier substrate 119. In some embodiments, the bonding layer 120 comprises a first bonding layer 121 on the first carrier substrate 119 and a second bonding layer 123 on the first bonding layer 121. The first bonding layer 121 may comprise a dielectric material, such as silicon oxynitride or the like and the second bonding layer 123 may comprise a dielectric material, such as silicon oxide or the like.

The bottom semiconductor die 100 may be attached to the first carrier substrate 119 by bonding the dielectric layer 118 and the bonding layer 120. The bonding process may include a pre-bonding and an annealing. During the pre-bonding, a small pressing force may be applied to press the bottom semiconductor die 100 against the bonding layer 120. The pre-bonding may be performed at a low temperature, such as room temperature, and after the pre-bonding, the dielectric layer 118 is bonded to the bonding layer 120. The bonding strength may be then improved in a subsequent annealing step, in which the dielectric layer 118 and the bonding layer 120 are annealed. After the annealing, dielectric-to-dielectric bond, such as covalent bond, may be formed, which bonds the dielectric layer 118 to the bonding layer 120.

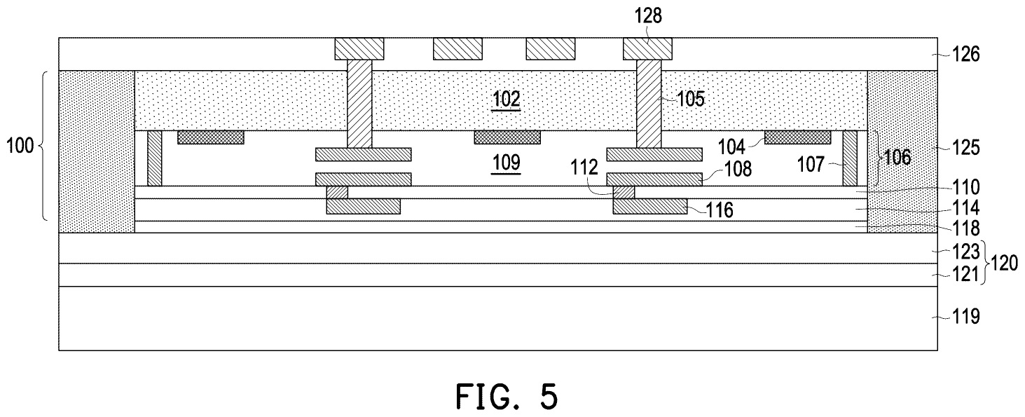

In FIG. 4, a bottom encapsulant 125 is formed over the first carrier substrate 119, and the substrate 102 and the bottom encapsulant 125 are thinned to expose the through vias 105. The bottom encapsulant 125 may extend along sidewalls of the bottom semiconductor die 100 and encircle the bottom semiconductor die 100 in the top-down view. In some embodiments, the bottom encapsulant 125 may comprise silicon oxide, silicon nitride, silicon carbide, silicon carbonitride, silicon oxynitride, silicon oxycarbonitride, un-doped silicate glass (USG), or the like, and may be formed using a suitable deposition process such as chemical vapor deposition (CVD), physical vapor deposition (PVD), atomic layer deposition (ALD), or the like. In some embodiments, the bottom encapsulant 125 may comprise a molding compound, an epoxy, a resin, or the like and may be formed by applying compression molding, transfer molding, or the like before being cured.

The substrate 102 is thinned to expose the through vias 105. Portions of the bottom encapsulant 125 may also be removed by the thinning process. The thinning process may be, a chemical-mechanical polish (CMP) process, a grinding process, an etch-back process, the like, or a combination thereof. In some embodiments, the substrate 102 is further recessed to expose sidewalls of the through vias 105. The recessing process may be a selective etching process, such as a dry etch, a wet etch, or combinations thereof. After the recessing process, the through vias 105 may protrude from the back side of the substrate 102.

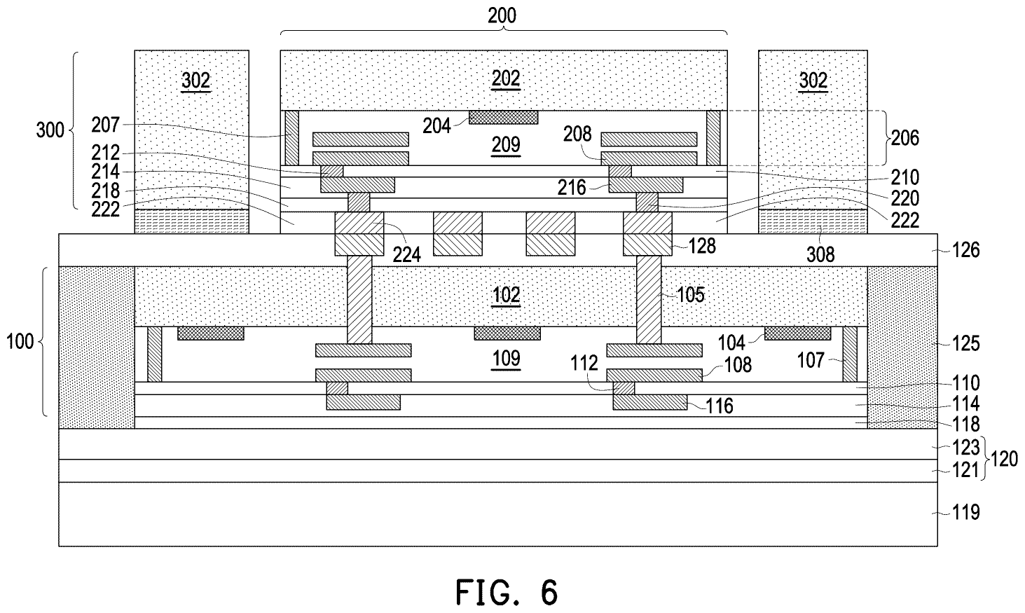

In FIG. 5, a bonding layer 126 is formed over the substrate 102, the bottom encapsulant 125, and the through vias 105, and bonding pads 128 are formed in the bonding layer 126. The bonding layer 126 may be used to bond to another device in a subsequent process. The bonding layer 126 may comprise silicon oxide, silicon nitride, silicon carbide, silicon carbonitride, silicon oxynitride, silicon oxycarbide, silicon oxycarbonitride, USG, or the like, and may be formed using a suitable deposition process such as CVD, PVD, ALD, or the like.

The bonding pads 128 are formed in the bonding layer 126 by techniques such as a damascene process, dual damascene process, or the like. The bonding pads 128 may be embedded in the bonding layer 126, wherein top surfaces of the bonding pads 128 are exposed, and sidewalls as well as bottom surfaces of the bonding pads 128 are in contact with the bonding layer 126. Some of the bonding pads 128 may be electrically connected to the through vias 105 and may be electrically connected to the electrical devices 104 of the bottom semiconductor die 100 by the through vias 105. As a result, the bonding pads 128 may provide external devices access to the electrical devices 104. Some of the bonding pads 128 may be dummy bonding pads and may be electrically isolated from the circuitry of the bottom semiconductor die 100.

As an example of forming the bonding pads 128, openings may be formed in the bonding layer 126 and may expose the underlying through vias 105. Forming the openings may include forming a patterned mask, such as a photoresist or one or more layers of dielectric material over the bonding layer 126, and performing a selective etching process, such as wet or dry etching, to remove the exposed portions of the bonding layer 126 and expose top surfaces of the through vias 105. The patterned mask may be removed after the etching process. The bonding pads 128 may be formed in the openings. The bonding pads 128 may comprise a conductive material, such as copper, aluminum, or the like, and formed by an electro-chemical plating process, an electroless plating process, CVD, ALD, PVD, the like, or a combination thereof. A planarization process, such as CMP, may be performed to remove the excess conductive material. As a result, top surfaces of the bonding layer 126 and the bonding pads 128 may be substantially co-planar or level.

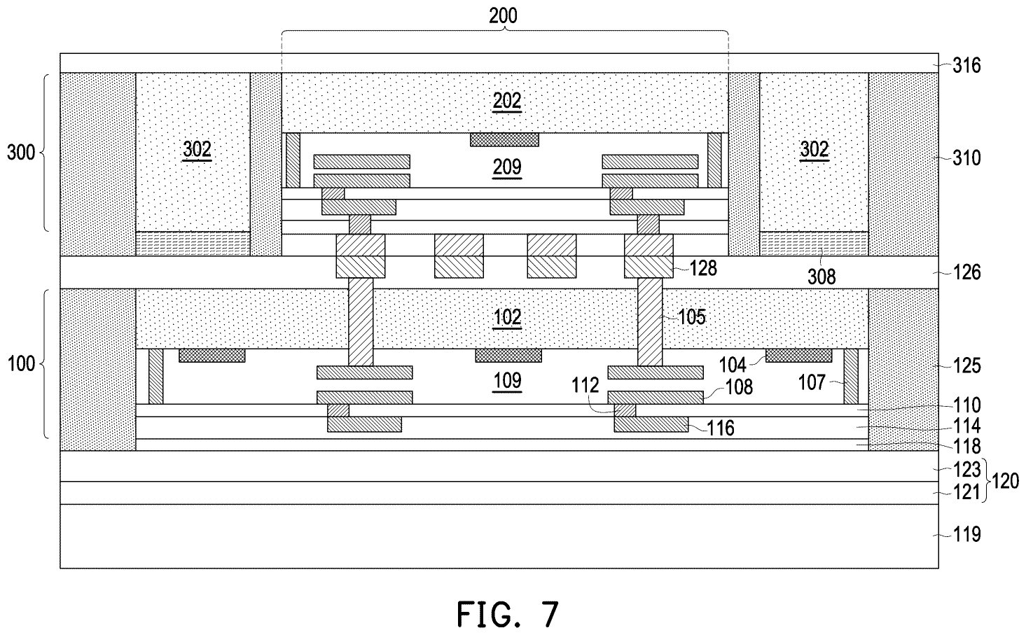

In FIG. 6, a top semiconductor die 200 is bonded to the bonding layer 126 and the bonding pads 128, and two dummy dies 300 are bonded to the bonding layer 126. One top semiconductor die 200 and two dummy dies 300 are illustrated as being bonded over the bottom semiconductor die 100 in FIG. 6 as an example, in some embodiments, other numbers of top semiconductor dies 200 and dummy dies 300 may be bonded over the bottom semiconductor die 100. The top semiconductor die 200 may be a bare semiconductor die (e.g., unpackaged semiconductor die) that is formed as part of a larger wafer or a package comprising one or more bare semiconductor dies, similar to the bottom semiconductor die 100. The top semiconductor die 200 may be processed according to applicable manufacturing processes to form integrated circuits in the top semiconductor die 200. The materials and manufacturing processes of the features in the top semiconductor die 200 may be found by referring to the like features in the bottom semiconductor die 100, wherein the like features in the bottom semiconductor die 100 having reference numerals starting with number “1” correspond to the features in the top semiconductor die 200 having reference numerals starting with number “2.”

The top semiconductor die 200 includes a substrate 202 and electrical devices 204 (i.e., active and/or passive devices), such as transistors, diodes, capacitors, resistors, and the like, formed in and/or on the substrate 202. The electrical devices 204 may generate relatively high levels of heat during operation, thereby creating thermal hotspots. An interconnect structure 206 is on the substrate 202. The interconnect structure 206 may include metallization patterns 208 in one or more dielectric layers 209, and the metallization patterns 208 electrically connect the electrical devices 204 on the substrate 202 to form one or more integrated circuits. Seal ring 207 may extend through the one or more dielectric layers 209 of the interconnect structure 206 and encircle the electrical devices 204 in the top-down view. In some embodiments, a back side of the substrate 202 may refer to a side of the substrate 202 opposite to the electrical devices 204 and the interconnect structure 206 while the front side of the substrate 202 may refer to a side of the substrate 202 on which the electrical devices 204 and the interconnect structure 206 are disposed.

The top semiconductor die 200 may further include one or more passivation layers 210 on the interconnect structure 206 and conductive vias 212 extending through the one or more passivation layers 210. The conductive vias 212 may be in electrical connection with the metallization patterns 108. A dielectric layer 214 is on the one or more passivation layers 210 and contact pads 216 are embedded in the dielectric layer 214. The contact pads 216 may be in electrical connection with the conductive vias 212. A dielectric layer 218 is on the dielectric layer 214, and conductive vias 220 extend through the dielectric layer 218 and into the dielectric layer 214. The conductive vias 212 may be in electrical connection with the contact pads 216. The conductive vias 220 may comprise a same or similar material as the conductive vias 212.

A bonding layer 222 is on the dielectric layer 218 and bonding pads 224 extend through the bonding layer 222. Some of the bonding pads 224 may be are electrically connected to the conductive vias 220 and may be electrically connected to the electrical devices 204 of the top semiconductor die 200. As a result, the bonding pads 224 may provide external devices access to the electrical devices 204. Some of the bonding pads 224 may be dummy bonding pads and may be electrically isolated from the circuitry of the top semiconductor die 200. Bottom surfaces of the bonding layer 222 and the bonding pads 224 may be substantially co-planar or level. The bonding layer 222 may be formed of a same or similar material and by a same or similar method as the bonding layer 126. The bonding pads 224 may be formed of a same or similar material and by a same or similar method as the bonding pads 128. The material of the bonding layer 126 and the bonding layer 222 may be selected so that dielectric-to-dielectric bonding may be formed between the bonding layer 126 and the bonding layer 222, and the material of the bonding pads 128 and the bonding pads 224 may be selected so that metal-to-metal bonding may be formed between the bonding pads 128 and the bonding pads 224, as discussed below.

The top semiconductor die 200 may be bonded to the bonding layer 126 and the bonding pads 128 on the bottom semiconductor die 100 using a bonding process, wherein the bonding layer 222 of the top semiconductor die 200 may be directly bonded to the bonding layer 126 on the bottom semiconductor die 100, and the bonding pads 224 of the top semiconductor die 200 may be directly bonded to the bonding pads 128 on the bottom semiconductor die 100. The top semiconductor die 200 may be disposed face down such that a front side of the substrate 202 faces the back side of the substrate 102, which may be referred to as a front-to-back package configuration. In some embodiments, the bond between the bonding layer 222 and the bonding layer 126 is a dielectric-to-dielectric bond, or the like, and the bond between the bonding pads 224 and the bonding pads 128 is a metal-to-metal bond. As a result, the bottom semiconductor die 100 and the top semiconductor die 200 may be electrically connected.

As an example, the bonding process may start with a surface treatment to the bonding layer 126 and the bonding layer 222. The surface treatment may include a plasma treatment in a vacuum environment. The surface treatment may further include a cleaning process, such as a rinse with deionized water, or the like. The bonding process may then proceed to aligning the bonding pads 224 to the bonding pads 128, so that the bonding pads 224 may overlap with the corresponding bonding pads 128. Next, the top semiconductor die 200 may be put in contact with the bonding layer 126 and the bonding pads 128 at room temperature (e.g., between about 21° C. and about 25° C.). A small pressing force may be applied to press the top semiconductor die 200 against the top semiconductor die 200. The bonding process may continue with performing an annealing, so that the metal in the bonding pads 224 and the metal in the bonding pads 128 inter-diffuse across the interfaces between the bonding pads 224 and the bonding pads 128, which forms the metal-to-metal bond, and the materials of bonding layer 126 and the bonding layer 222 react to form dielectric-to-dielectric bond.

Each dummy die 300 may comprise a substrate 302 and a dielectric layer 308 on the substrate 302. The dielectric layer 308 may be a bonding layer that may bond the dummy die 300 to the bonding layer 126. During the bonding process, the dielectric layer 308 of each dummy die 300 may be bonded to the bonding layer 126 by dielectric-to-dielectric bonding, which is similar to the bonding between the bonding layer 222 and the bonding layer 126. After the bonding process, sides of the substrates 302 facing the bonding layer 126 may be referred to as front sides of the substrates 302, and sides of the substrates 302 opposite the front sides of the substrates 302 may be referred to as back sides of the substrates 302. The substrate 302 may comprise a same or similar material as the substrate 102. The dielectric layer 308 may comprise silicon oxide, silicon oxynitride, silicon oxycarbide, or the like.

The manufacturing processes discussed above correspond to a front-to-back bonding configuration between top semiconductor die 200 and the bottom semiconductor die 100 the as an example. In the front-to-back package configuration, the top semiconductor die 200 and the bottom semiconductor die 100 are oriented such that the front side of the substrate 202 of the top semiconductor die 200 faces the back side of the substrate 102 of the bottom semiconductor die 100. Other bonding configurations, such as front-to-front package configuration, are also contemplated. In the front-to-front package configuration, the top semiconductor die 200 and the bottom semiconductor die 100 are oriented such that the front side of the substrate 202 of the top semiconductor die 200 faces the front side of the substrate 102 of the bottom semiconductor die 100.

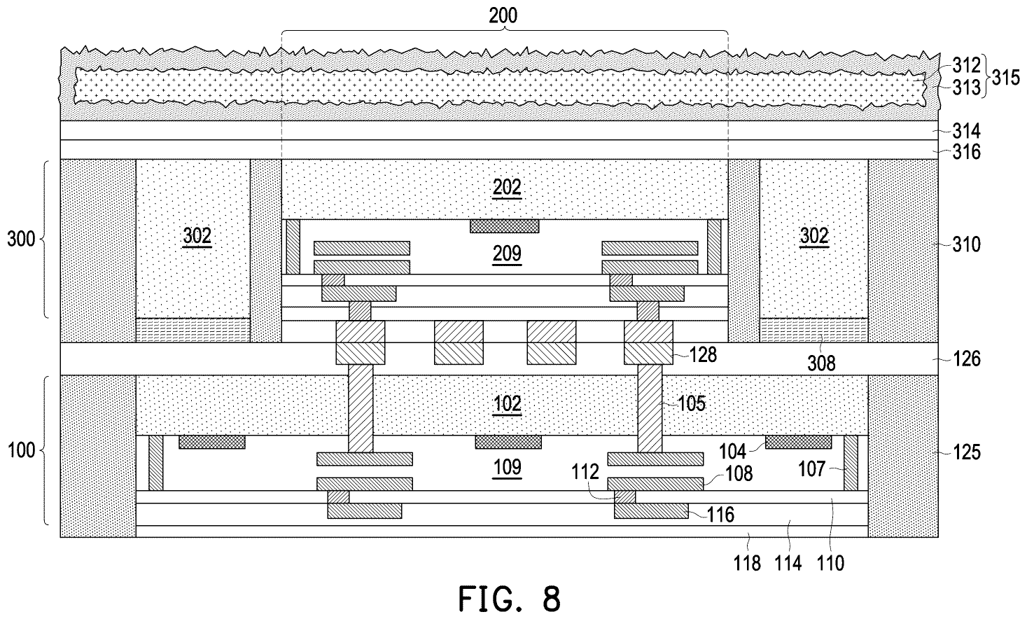

In FIG. 7, a top encapsulant 310 is formed over the remaining portions of the bonding layer 126, and a dielectric layer 316 is formed on the top encapsulant 310, the top semiconductor die 200, and the dummy dies 300. The top encapsulant 310 may extend along sidewalls of the top semiconductor die 200 and the dummy dies 300, and encircle the top semiconductor die 200 and the dummy dies 300 in the top-down view. The top encapsulant 310 may be formed of a same or similar material and formed by a same or similar method as the bottom encapsulant 125. A thinning process may be applied to expose the substrate 202 and the substrates 302. The thinning process may comprise performing a CMP process, a grinding process, an etch-back process, combinations thereof, or the like. As a result, the back side of the substrate 202, back sides of the substrates 302, and a top surface of the top encapsulant 310 may be substantially co-planar or level. The dielectric layer 316 may be formed of a same or similar material and formed by a same or similar method to the bonding layer 126. The dielectric layer 316 may act as a bonding layer in a subsequent process.

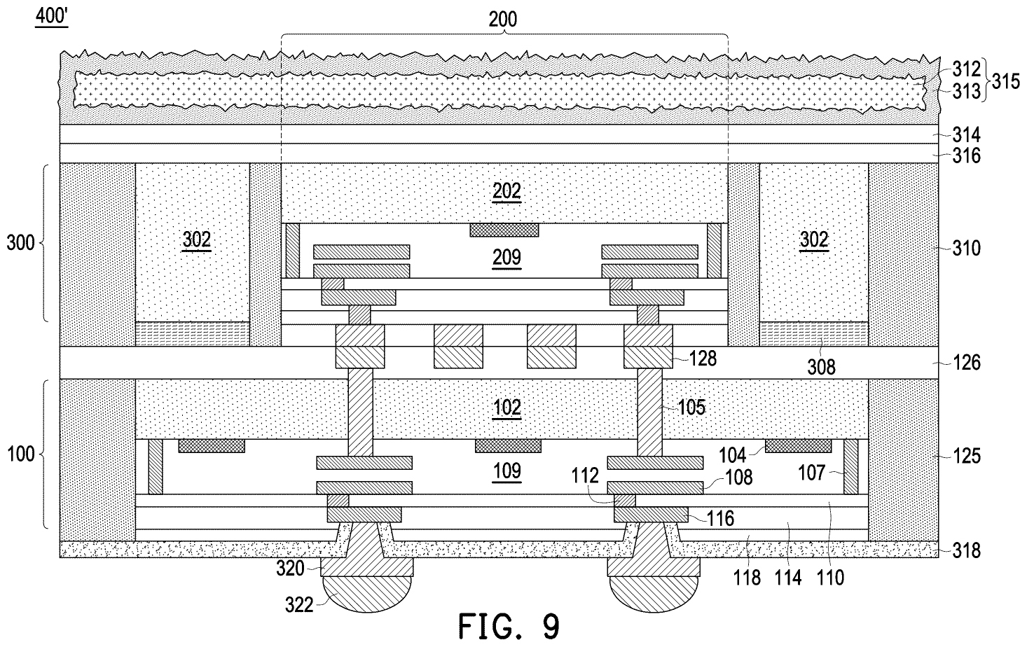

In FIG. 8, the structure over the first carrier substrate 119 (shown in FIG. 7) is bonded to the second carrier substrate 315, and the first carrier substrate 119 and the bonding layer 120 are removed. Prior to the bonding process, a bonding layer 314 may be formed on the bottom surface of the second carrier substrate 315. The bonding layer 314 may be formed of a same or similar material and formed by a same or similar method to the bonding layer 126. The structure over the first carrier substrate 119 may be bonded to the second carrier substrate 315 by bonding the dielectric layer 316 and the bonding layer 314 by a same or similar process as used for bonding the bonding layer 126 and the bonding layer 222. Since the bottom surface of the second carrier substrate 315 has a low roughness as described above, a bottom surface of the bonding layer 314 facing the dielectric layer 316 may also have a low roughness. As a result, the bonding strength between the dielectric layer 316 and the bonding layer 314 may be improved. The first carrier substrate 119 and the bonding layer 120 may be removed by a thinning process. The thinning process may be a CMP process, a grinding process, an etch-back process, combinations thereof, or the like. After the thinning process, bottom surfaces of the dielectric layer 118 and the bottom encapsulant 125 may be substantially co-planar or level.

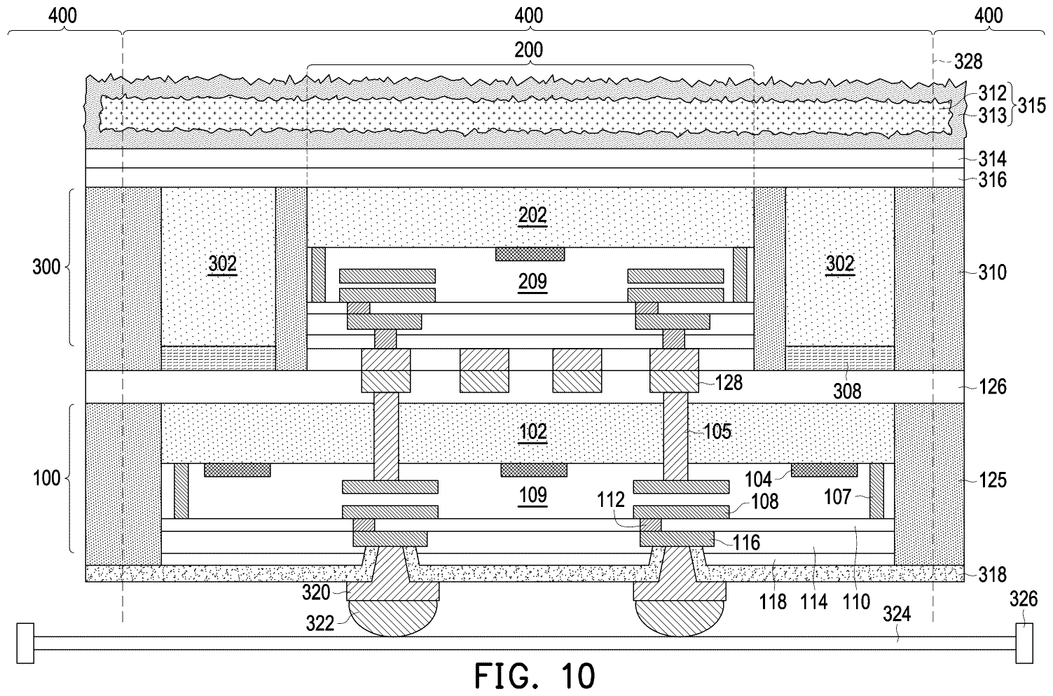

In FIG. 9, openings are formed through the dielectric layer 118 and the dielectric layer 114 to expose the contact pads 116, and a protective layer 318 is formed on the bottom surfaces of the dielectric layer 118 and the bottom encapsulant 125. Further under-bump metallizations (UBMs) 320 are formed in the openings and electrical connectors 322 are formed on the UBMs 320. The openings may be formed by a same or similar method with respect to the openings in which the bonding pads 128 are formed. The openings may expose the contact pads 116 as well as sidewalls of the dielectric layer 118 and the dielectric layer 114. The protective layer 318 may be formed of an insulating material, such as polyimide or the like, and by a coating method, such as spin-coating or the like. The protective layer 318 may cover the exposed portions of contact pads 116 and sidewalls of the dielectric layer 118 and the dielectric layer 114, as well as the bottom surfaces of the dielectric layer 118 and the bottom encapsulant 125. Then portions of the protective layer 318 that cover the exposed portions of contact pads 116 may be removed to re-expose contact pads 116.

The UBMs 320 have bump portions on and extending along a surface of the protective layer 318, and have via portions extending through the openings to connect to the contact pads 116. As a result, the UBMs 320 are electrically connected to the bottom semiconductor die 100. As an example to form the UBMs 320, a seed layer may be formed on the protective layer 318 and on the exposed portions of the contact pads 116. The seed layer may be a metal layer, which may be a single layer or a composite layer comprising a plurality of sub-layers formed of different materials formed using a deposition process, such as PVD or the like. A photoresist may be then formed and patterned on the seed layer. The pattern of the photoresist may have openings through the photoresist to expose the seed layer and may correspond to the UBMs 320. A conductive material may be formed in the openings of the photoresist and on the exposed portions of the seed layer by plating, such as electroless plating, electroplating, or the like. The conductive material may comprise a metal or a metal alloy, such as copper, titanium, tungsten, aluminum, the like, or combinations thereof. Then, the photoresist and portions of the seed layer on which the conductive material is not formed may be removed by an acceptable ashing or stripping process, such as using an oxygen plasma or the like. Once the photoresist is removed, exposed portions of the seed layer may be are removed, by using an acceptable etching process, such as by wet or dry etching. The remaining portions of the seed layer and conductive material may be collectively referred to as the UBMs 320.

Electrical connectors 322 are formed on the UBMs 320. The UBMs 320 and the electrical connectors 322 may be used to provide input/output connections to external electrical components, such as, other device dies, redistribution structures, printed circuit boards (PCBs), motherboards, or the like. The electrical connectors 322 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The electrical connectors 322 may include a conductive material such as solder, copper, aluminum, gold, nickel, silver, palladium, tin, the like, or a combination thereof. In some embodiments, the electrical connectors 322 are formed by initially forming a layer of solder through evaporation, electroplating, printing, solder transfer, ball placement, or the like and reflowing the layer of solder to shape the material into the desired bump shapes. In some embodiments, the electrical connectors 322 comprise metal pillars (such as a copper pillar) formed by a sputtering, printing, electro plating, electroless plating, CVD, or the like. The structure shown in FIG. 9 may be referred to as a wafer structure 400′.

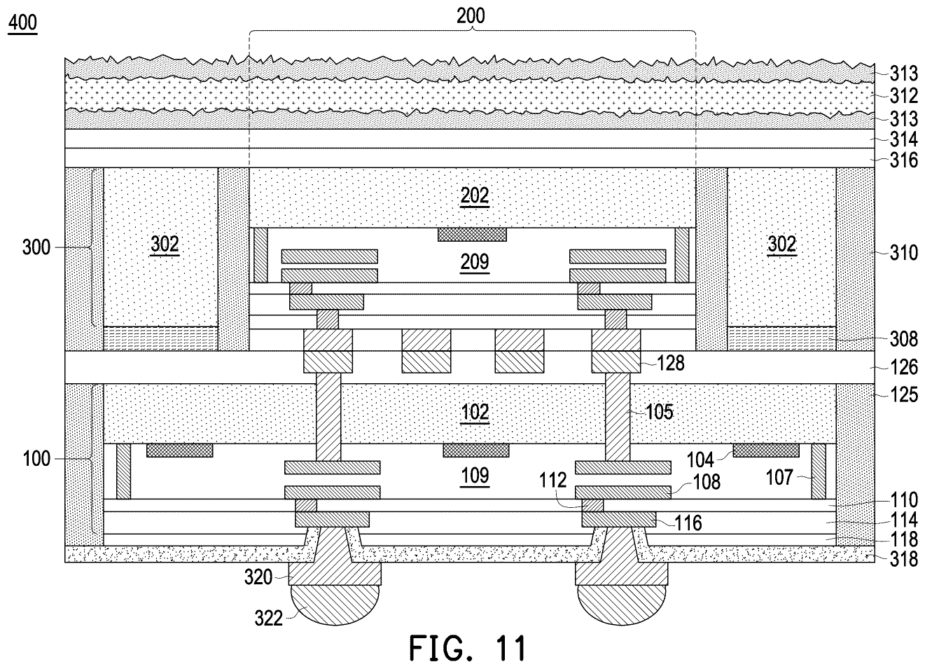

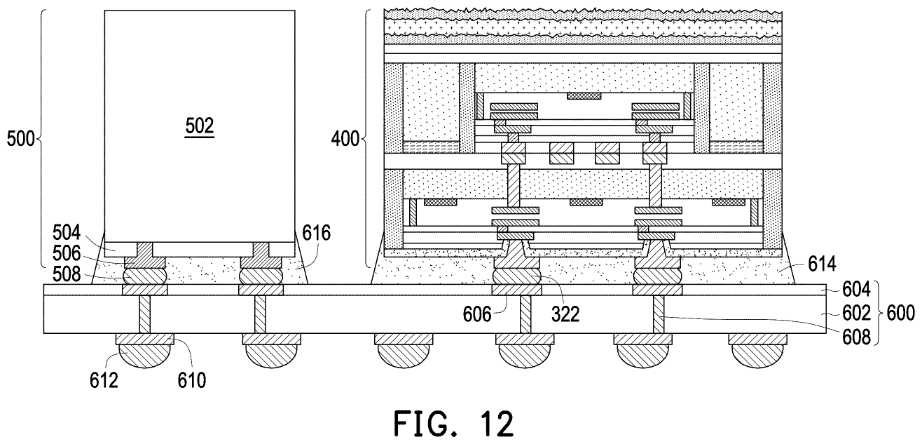

In FIG. 10, the wafer structure 400′ is singulated into discrete semiconductor package components 400. The wafer structure 400′ may be placed on a tape 324 supported by a frame 326. The wafer structure 400′ may be then singulated along scribe lines 328, so that the wafer structure 400′ is separated into discrete semiconductor package components 400. The singulation process may include a sawing process, a laser cutting process, or the like. A cleaning process or rinsing process may be performed after the singulation process. Each semiconductor package component 400 may be then removed from the tape 324 as shown in FIG. 11. In the semiconductor package component 400, the singulated second carrier substrate 315 may comprise the singulated wafer 312 (referred to as a base portion 312 from here on) and the singulated coating layer 313. The singulated coating layer 313 may comprise a first coating portion 313 on a top surface (the surface facing upward in FIG. 11) of the base portion 312 and a second coating portion 313 on a bottom surface (the surface facing downward in FIG. 11) of the base portion 312. Sidewalls of the base portion 312 may be exposed.

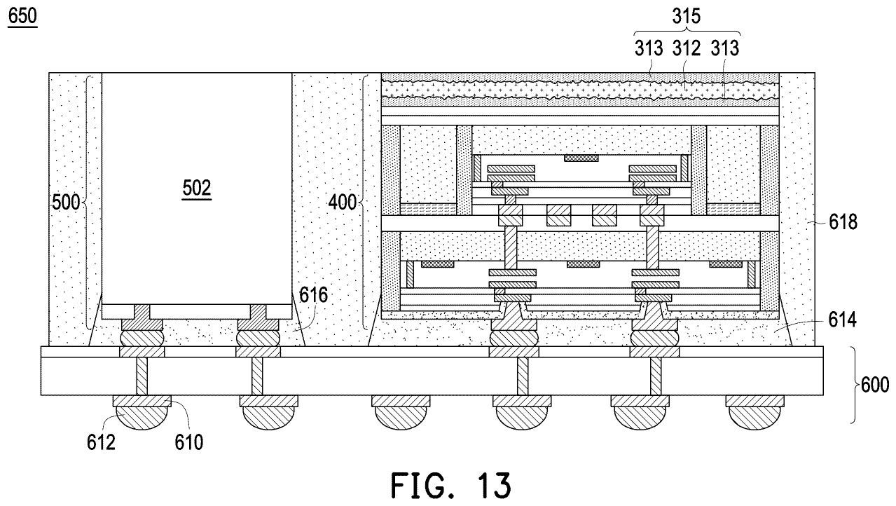

In FIG. 12, the semiconductor package component 400 is bonded to a semiconductor package component 600 and an underfill 614 is formed between the semiconductor package component 400 and the semiconductor package component 600. Further, a semiconductor package component 500 is bonded to the semiconductor package component 600 and an underfill 616 is formed between the semiconductor package component 500 and the semiconductor package component 600. The semiconductor package component 600 may comprise a substrate 602, one or more dielectric layers 604 on a first side of the substrate 602, conductive features 606 in the dielectric layers 604, and conductive features 610 on a second side of the substrate 602. The conductive features 606 may comprise conductive lines, conductive vias, and conductive pads. Through-substrate vias 608 may extend through the substrate 602 and may interconnect the conductive features 606 to the conductive features 610. Electrical connectors 612 may be on the conductive features 610. The semiconductor package component 600 may be referred to as an interposer.

During the bonding process between the semiconductor package component 400 and semiconductor package component 600, the electrical connectors 322 may be reflowed to bond the semiconductor package component 400 to the conductive features 606. The electrical connectors 322 may electrically connect the semiconductor package component 600 to the semiconductor package component 400. The underfill 614 may surround the electrical connectors 322 and protect the joints resulting from the reflowing of the electrical connectors 322. The underfill 614 may encircle the semiconductor package component 400 in the top-down view. The underfill 614 may be formed of a molding compound, epoxy, or the like and formed by a capillary flow process after the semiconductor package component 400 is bonded. The underfill 614 may be subsequently cured.

The semiconductor package component 500 may comprise one or more integrated circuit dies in an active region 502 of the semiconductor package component 500. In some embodiments, the active region 502 comprises a stack of interconnected memory dies and the semiconductor package component 500 is referred to as a high bandwidth memory (HBM) device. One or more dielectric layers 504 may be on a first side of the active region 502, conductive features 506 may be in and on the dielectric layers 504. The conductive features 506 may comprise conductive lines, conductive vias, and conductive pads. Electrical connectors 508 may be on the conductive features 506.

During the bonding process between the semiconductor package component 500 and semiconductor package component 600, the electrical connectors 508 may be reflowed to bond the semiconductor package component 500 to the conductive features 606. The electrical connectors 508 may electrically connect the semiconductor package component 600 to the semiconductor package component 500. The underfill 616 may surround the electrical connectors 508 and protect the joints resulting from the reflowing of the electrical connectors 508. The underfill 616 may encircle the semiconductor package component 500 in the top-down view. The underfill 616 may be formed of a same or similar material and formed by a same or similar process to the underfill 614.

In FIG. 13, an encapsulant 618 is formed on the semiconductor package component 600. The structure shown in FIG. 13 may be referred to as a semiconductor package component 650. The encapsulant 618 may extend along sidewalls of the semiconductor package component 400 and the semiconductor package component 500, and encircle the semiconductor package component 400 and the semiconductor package component 500 in the top-down view. The encapsulant 618 may be formed of a same or similar material and formed by a same or similar method to the bottom encapsulant 125. A planarization process may be applied to expose the second carrier substrate 315 and the active region 502. The planarization process may be CMP, a grinding, or the like. After the planarization process, top surfaces of the second carrier substrate 315, the active region 502, and the encapsulant 618 may be substantially co-planar or level.

As a result of the planarization process, a top surface of the first coating portion 313 of the second carrier substrate 315 (e.g., the top surface of the second carrier substrate 315) may have a third roughness (e.g., an average roughness (Ra)) smaller than about 10 nm. The third roughness may be smaller than the first roughness of the surfaces of the base portion 312, and larger than or equal to the second roughness of the bottom surface of the second coating portion 313 (e.g., the bottom surface of the second carrier substrate 315). The second carrier substrate 315 may be attached to a lid as described in greater detail below. Since the top surface of the second carrier substrate 315 has a low roughness as described above, the attachment of the lid to the second carrier substrate 315 may be more effective. When the top surface of the coating layer 313 has a surface roughness less than 10 nm, improved attachment strength between the second carrier substrate 315 and the lid may be achieved.

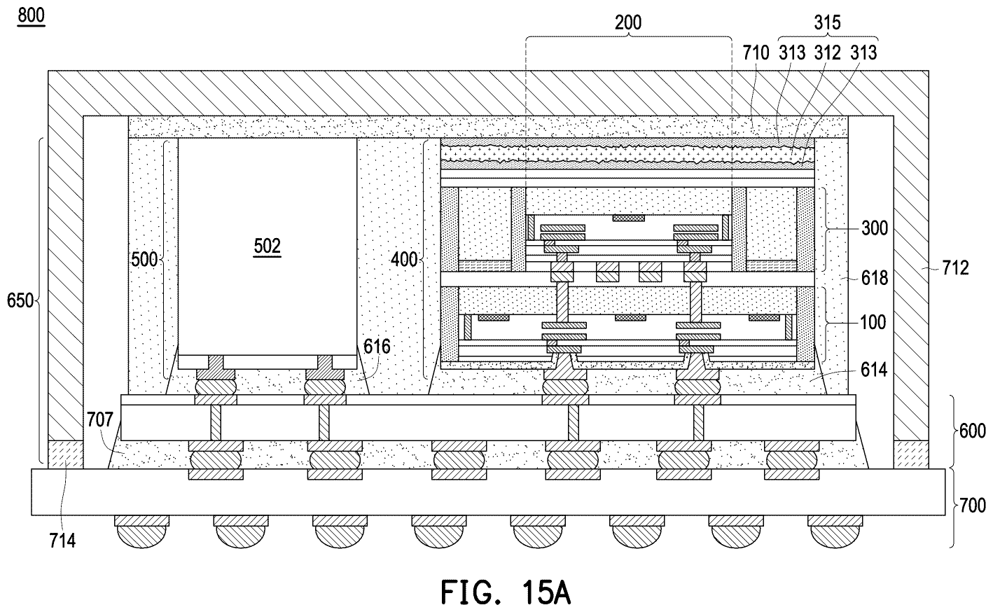

In FIG. 14, the semiconductor package component 650 is bonded to a package substrate 700 and an underfill 707 is formed between the semiconductor package component 650 and the package substrate 700. The package substrate 700 may comprise a substrate core 702, conductive contacts 704 on a first side of the substrate core 702, and conductive contacts 706 on a second side of the substrate core 702. The conductive contacts 704 may be electrically connected to the conductive contacts 706 by conductive features inside the substrate core 702 (not shown). Electrical connectors 708 may be on the conductive contacts 706. During the bonding process between the semiconductor package component 650 and the package substrate 700, the electrical connectors 612 may be reflowed to bond the semiconductor package component 650 to the package substrate 700. The electrical connectors 612 may electrically connect the semiconductor package component 650 to the package substrate 700. The underfill 707 may surround the electrical connectors 612 and protect the joints resulting from the reflowing of the electrical connectors 612. The underfill 707 may encircle the semiconductor package component 650 in the top-down view. The underfill 707 may be formed of a same or similar material and formed by a same or similar process to the underfill 614.

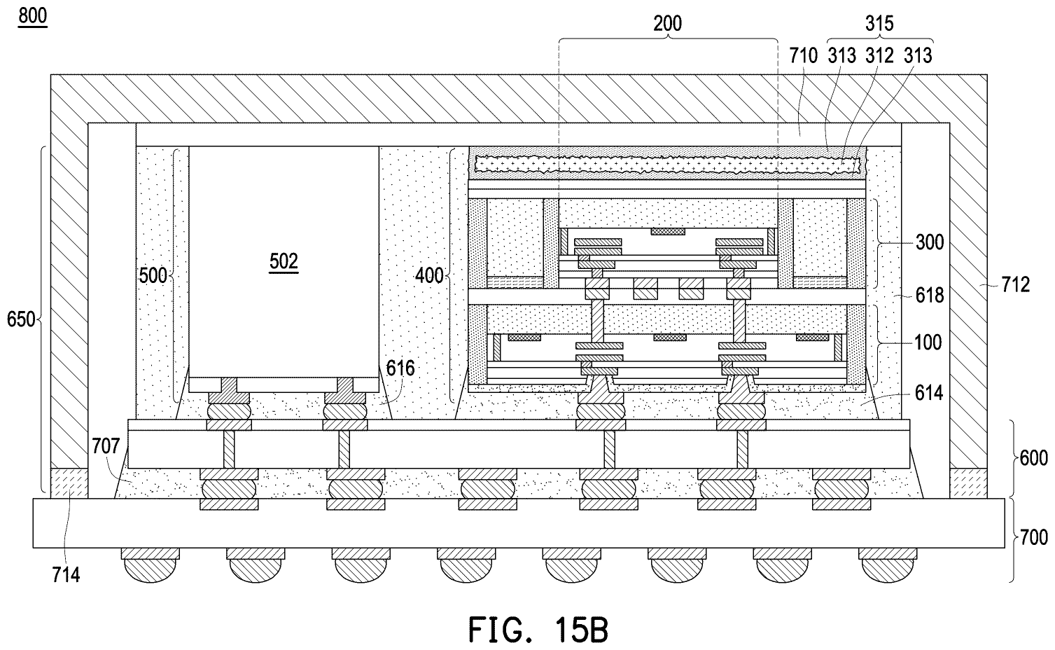

In FIG. 15A, a lid 712 is attached to the package substrate 700 and the semiconductor package component 650. The structure shown in FIG. 15A may be referred to as a semiconductor package 800. The lid 712 may protect the structural integrity of the semiconductor package component 650 and dissipate heat generated by the semiconductor package component 650 during operation of the semiconductor package 800. The lid 712 may be formed of a metal or a metal alloy, such as copper, stainless steel, or the like. The lid 712 may be attached to the package substrate 700 by adhesive layers 714, which may comprise epoxy, glue, or the like. The lid 712 may be attached to the semiconductor package component 650 by an adhesive layer 710, which may comprise a thermal interface material (TIM) with high thermal conductivity, such as, thermal paste, gel-based thermal adhesive, graphite, graphene, the like, or the combinations thereof. The top surface of the first coating portion 313 of the second carrier substrate 315 (e.g., the top surface of the second carrier substrate 315) may be in contact with the adhesive layer 710. Since the top surface of the second carrier substrate 315 has a low roughness as described above, the attachment of the lid 712 to the second carrier substrate 315 may be more effective.

Since the second carrier substrate 315 is more effectively bonded over the top semiconductor die 200 and the bottom semiconductor die 100 due to the low roughness of the bottom surface of the second carrier substrate 315, during the operation of the semiconductor package 800, the heat generated by the top semiconductor die 200 may be more effectively transferred to the second carrier substrate 315 directly, and the heat generated by the bottom semiconductor die 100 may be more effectively transferred to the second carrier substrate 315 by the dummy dies 300. Since the material of the base portion 312 of the second carrier substrate 315 has a high thermal conductivity and the second carrier substrate 315 is more effectively attached to the lid 712 due to the low roughness of the top surface of the second carrier substrate 315, the heat generated by the top semiconductor die 200 and the bottom semiconductor die 100 may be more effectively transferred from the second carrier substrate 315 to the lid 712, where said heat may be dissipated. As a result, the performance and reliability of the semiconductor package 800 may be improved.

FIG. 15B shows a semiconductor package 800 in accordance with some alternative embodiments similar to the embodiments of the semiconductor package 800 shown in FIG. 15A, wherein like numerals refer to like features formed of like materials and by like processes. The semiconductor package 800 in FIG. 15B may include the wafer structure 400′ as shown in FIG. 9 without being subsequently singulated. As a result, the second carrier substrate 315 may include the wafer 312 and the coating layer 313 on the top surface, the bottom surface, and the sidewalls of the wafer 312. The top surface and the bottom surface of the wafer 312, may have the first roughness (e.g., an average roughness (Ra)) in a range from about 0.3 nm to about 30 nm. The bottom surface of the coating layer 313 (e.g., the bottom surface of the second carrier substrate 315) may be planarized by the process described with respect to FIG. 2A and may have the second roughness (e.g., an average roughness (Ra)) smaller than about 0.3 nm. The top surface of the coating layer 313 (e.g., the top surface of the second carrier substrate 315) may be planarized by the process described with respect to FIG. 13 and may have a third roughness (e.g., an average roughness (Ra)) smaller than about 10 nm.

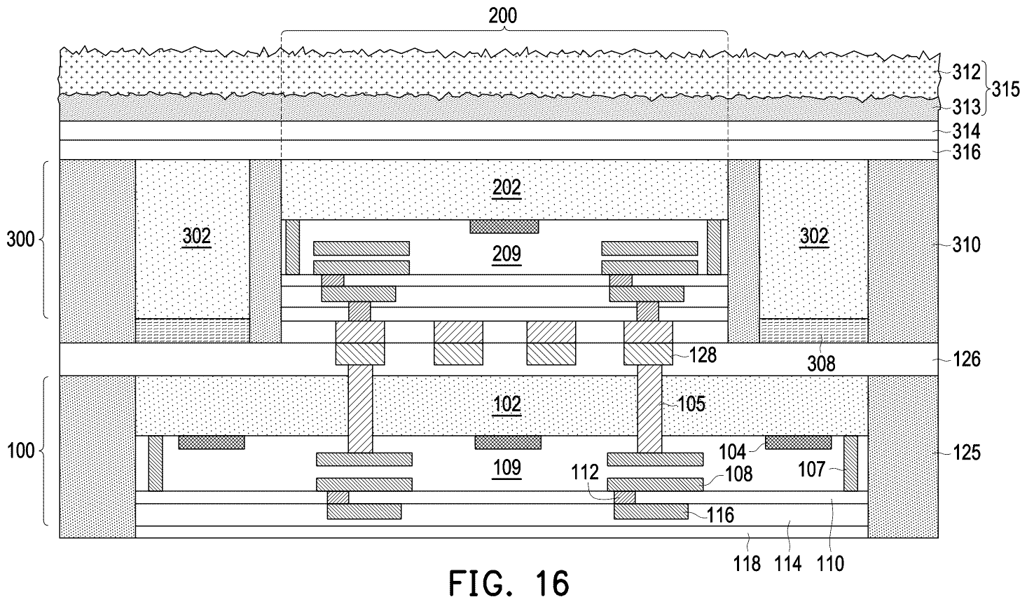

FIGS. 16, 17, 18, and 19 illustrate cross-sectional views of intermediate steps during the manufacturing of a semiconductor package using the carrier substrate, in accordance with some embodiments. FIG. 16 shows a structure in accordance with some alternative embodiments similar to the embodiments of the structure shown in FIG. 8, wherein like numerals refer to like features formed of like materials and by like processes. The structure in FIG. 16 comprises the embodiments of the second carrier substrate 315 shown in FIG. 2B, where the coating layer 313 is formed on the bottom surface of the wafer 312 and other surfaces of the wafer 312 are exposed.

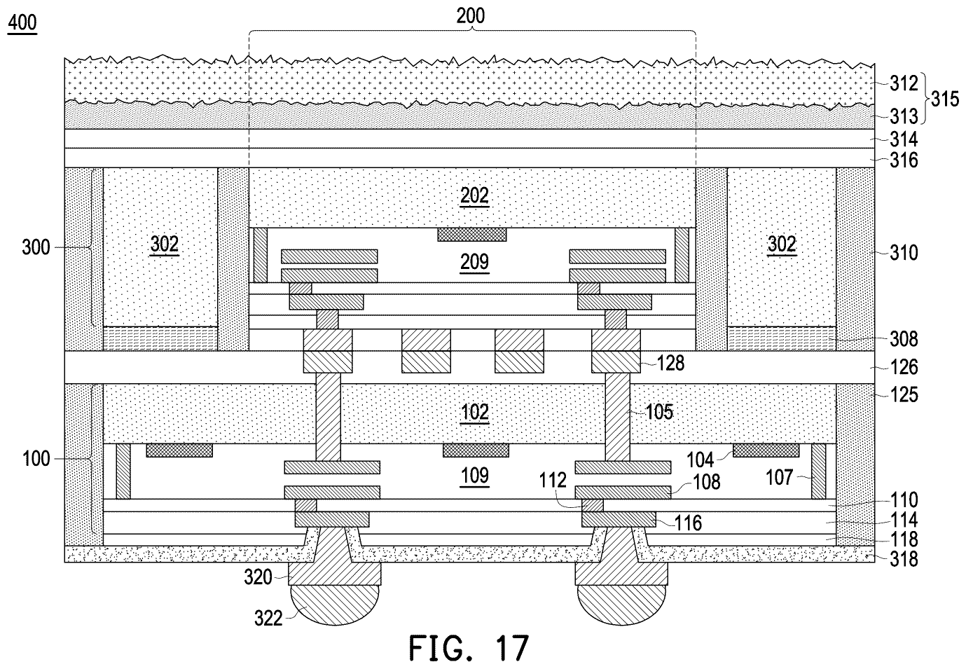

FIG. 17 shows a semiconductor package component 400 in accordance with some alternative embodiments similar to the embodiments of the semiconductor package component 400 shown in FIG. 11, wherein like numerals refer to like features formed of like materials and by like processes. The semiconductor package component 400 in FIG. 17 may be a resulting structure after the processes described with respect to FIGS. 9 through 11 are performed on the structure shown in FIG. 16. In the semiconductor package component 400, the singulated second carrier substrate 315 may comprise the singulated wafer 312 (referred to as the base portion 312) and the singulated coating layer 313. The singulated coating layer 313 may be referred to as the coating portion 313 on the bottom surface (the surface facing downward in FIG. 17) of the base portion 312. The top surface (the surface facing upward in FIG. 17) and sidewalls of the base portion 312 may be exposed.

FIG. 18 shows a semiconductor package component 650 in accordance with some alternative embodiments similar to the embodiments of the semiconductor package component 650 shown in FIG. 13, wherein like numerals refer to like features formed of like materials and by like processes. The semiconductor package component 650 in FIG. 18 may be a resulting structure after the processes described with respect to FIGS. 12 through 13 are performed on the semiconductor package component 400 shown in FIG. 16. As a result of the planarization process, the top surface of the base portion 312 of the second carrier substrate 315 (e.g., the top surface of the second carrier substrate 315) may have a fourth roughness (e.g., an average roughness (Ra)) in range from about 0.5 nm to about 10 nm. The fourth roughness may be smaller than the first roughness of the bottom surface of the base portion 312, and larger than the second roughness of the bottom surface of the coating portion 313 (e.g., the bottom surface of the second carrier substrate 315). The second carrier substrate 315 may be attached to a lid as described in greater detail below. Since the top surface of the second carrier substrate 315 has a low roughness as described above, the attachment of the lid to the second carrier substrate 315 may be more effective. When the top surface of base portion 312 has a surface roughness in range from about 0.5 nm to about 10 nm, improved attachment strength between the second carrier substrate 315 and the lid may be achieved.

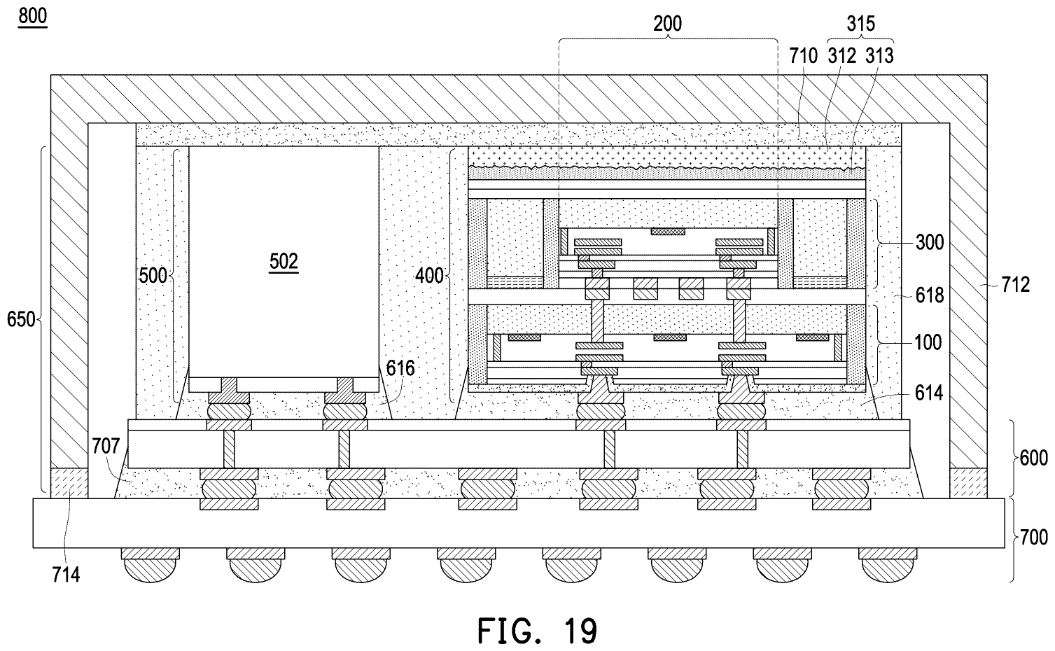

FIG. 19 shows a semiconductor package 800 in accordance with some alternative embodiments similar to the embodiments of the semiconductor package 800 shown in FIG. 15A, wherein like numerals refer to like features formed of like materials and by like processes. The semiconductor package 800 in FIG. 19 may be a resulting structure after the processes described with respect to FIGS. 14 through 15 are performed on the semiconductor package component 650 shown in FIG. 18. The top surface of the base portion 312 of the second carrier substrate 315 (e.g., the top surface of the second carrier substrate 315) may be in contact with the adhesive layer 710. Since the top surface of the second carrier substrate 315 has a low roughness as described above, the attachment of the lid 712 to the second carrier substrate 315 may be more effective.

Since the second carrier substrate 315 is more effectively bonded over the top semiconductor die 200 and the bottom semiconductor die 100 due to the low roughness of the bottom surface of the second carrier substrate 315, during the operation of the semiconductor package 800, the heat generated by the top semiconductor die 200 may be more effectively transferred to the second carrier substrate 315 directly, and the heat generated by the bottom semiconductor die 100 may be more effectively transferred to the second carrier substrate 315 by the dummy dies 300. Since the material of the base portion 312 of the second carrier substrate 315 has a high thermal conductivity and the second carrier substrate 315 is more effectively attached to the lid 712 due to the low roughness of the top surface of the second carrier substrate 315, the heat generated by the top semiconductor die 200 and the bottom semiconductor die 100 may be more effectively transferred from the second carrier substrate 315 to the lid 712, where said heat may be dissipated. As a result, the performance and reliability of the semiconductor package 800 may be improved.

The embodiments of the present disclosure have some advantageous features. By utilizing the second carrier substrate 315, the heat generated by the top semiconductor die 200 and the bottom semiconductor die 100 in the semiconductor package 800 may be more effectively transferred to the second carrier substrate 315, and then to the lid 712, where said heat may be dissipated. As a result, the performance and reliability of the semiconductor package 800 may be improved.

In an embodiment, a semiconductor package includes a package substrate; and a first package component over the package substrate, the first package component including: a first semiconductor die; and a heat dissipation substrate over the first semiconductor die, the heat dissipation substrate including: a base portion, wherein the base portion includes a first material with a first thermal conductivity; and a first coating portion on a first surface of the base portion, wherein the first coating portion is between the first semiconductor die and the base portion, wherein the first coating portion includes a second material different from the first material, and wherein the second material has a second thermal conductivity smaller than the first thermal conductivity. In an embodiment, the first thermal conductivity is greater than 170 W/mK. In an embodiment, the first material is silicon carbide or aluminum nitride. In an embodiment, the second material is silicon, silicon nitride, or aluminum oxide. In an embodiment, a first surface of the first coating portion faces the first semiconductor die, and wherein an average roughness of the first surface of the first coating portion is smaller than 0.3 nm. In an embodiment, the heat dissipation substrate further includes a second coating portion on a second surface of the base portion, wherein the second surface of the base portion is opposite to the first surface of the base portion, and wherein the second coating portion includes the second material. In an embodiment, the semiconductor further includes a lid over the package substrate and the first package component; and a first adhesive layer, wherein the lid is attached to the heat dissipation substrate of the first package component by the first adhesive layer. In an embodiment, the base portion has a first thickness and the first coating portion has a second thickness, and wherein a ratio of the second thickness to the first thickness is smaller than 0.0002.

In an embodiment, a method of manufacturing a semiconductor package includes forming a carrier substrate, forming the carrier substrate including: depositing a coating portion on a base portion, wherein the coating portion and the base portion include different materials, and wherein the base portion has a higher thermal conductivity than the coating portion; and planarizing a first surface of the coating portion; bonding the carrier substrate over a first semiconductor die, wherein the first surface of the coating portion faces the first semiconductor die; and attaching a lid to the carrier substrate, wherein the carrier substrate is between the first semiconductor die and the lid. In an embodiment, the lid is attached to the coating portion of the carrier substrate by a first adhesive layer. In an embodiment, the method further includes planarizing a second surface of the coating portion before attaching the lid, wherein the second surface of the coating portion faces the lid. In an embodiment, the lid is attached to the base portion of the carrier substrate by a first adhesive layer. In an embodiment, the method further includes planarizing the base portion before attaching the lid. In an embodiment, a thermal conductivity of the base portion is greater than 170 W/mK.

In an embodiment, a method of manufacturing a semiconductor package includes depositing a first coating portion on a first surface of a base portion to form a carrier substrate, wherein the base portion includes a first material with a first thermal conductivity greater than 170 W/mK; bonding the carrier substrate over a first semiconductor die, wherein a first surface of the first coating portion faces the first semiconductor die; and bonding the first semiconductor die over a package substrate, wherein the first semiconductor die is electrically connected to the package substrate. In an embodiment, the first material is a polycrystalline semiconductor material or a polycrystalline dielectric material. In an embodiment, the first coating portion includes a second material different from the first material, and wherein the second material is a polycrystalline semiconductor material or a polycrystalline dielectric material. In an embodiment, the method further includes planarizing the first surface of the first coating portion before bonding the carrier substrate over the first semiconductor die, wherein an average roughness of the first surface of the first coating portion is smaller than 0.3 nm after planarizing the first surface of the first coating portion. In an embodiment, the method further includes including depositing a second coating portion on a second surface of the base portion opposite the first surface, wherein the first coating portion and the second coating portion include a same material. In an embodiment, the method further includes planarizing a first surface of the second coating portion, wherein an average roughness of the first surface of the second coating portion is smaller than 10 nm after planarizing the first surface of the second coating portion.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package comprising:
a package substrate; and
a first package component over the package substrate, the first package component comprising:
a first semiconductor die; and
a heat dissipation substrate over the first semiconductor die, the heat dissipation substrate comprising:
a base portion, wherein the base portion comprises a first material with a first thermal conductivity; and
a first coating portion on a first surface of the base portion, wherein the first coating portion is between the first semiconductor die and the base portion, wherein the first coating portion comprises a second material different from the first material, and wherein the second material has a second thermal conductivity smaller than the first thermal conductivity.

2. The semiconductor package of claim 1, wherein the first thermal conductivity is greater than 170 W/mK.

3. The semiconductor package of claim 1, wherein the first material is silicon carbide or aluminum nitride.

4. The semiconductor package of claim 1, wherein the second material is silicon, silicon nitride, or aluminum oxide.

5. The semiconductor package of claim 1, wherein a first surface of the first coating portion faces the first semiconductor die, and wherein an average roughness of the first surface of the first coating portion is smaller than 0.3 nm.

6. The semiconductor package of claim 1, wherein the heat dissipation substrate further comprises a second coating portion on a second surface of the base portion, wherein the second surface of the base portion is opposite to the first surface of the base portion, and wherein the second coating portion comprises the second material.

7. The semiconductor package of claim 1, further comprising:
a lid over the package substrate and the first package component; and
a first adhesive layer, wherein the lid is attached to the heat dissipation substrate of the first package component by the first adhesive layer.

8. The semiconductor package of claim 1, wherein the base portion has a first thickness and the first coating portion has a second thickness, and wherein a ratio of the second thickness to the first thickness is smaller than 0.0002.

9. A method of manufacturing a semiconductor package, the method comprising:
forming a carrier substrate, forming the carrier substrate comprising:
depositing a coating portion on a base portion, wherein the coating portion and the base portion comprise different materials, and wherein the base portion has a higher thermal conductivity than the coating portion; and
planarizing a first surface of the coating portion;
bonding the carrier substrate over a first semiconductor die, wherein the first surface of the coating portion faces the first semiconductor die; and
attaching a lid to the carrier substrate, wherein the carrier substrate is between the first semiconductor die and the lid.

10. The method of claim 9, wherein the lid is attached to the coating portion of the carrier substrate by a first adhesive layer.

11. The method of claim 10, further comprising planarizing a second surface of the coating portion before attaching the lid, wherein the second surface of the coating portion faces the lid.

12. The method of claim 9, wherein the lid is attached to the base portion of the carrier substrate by a first adhesive layer.

13. The method of claim 12, further comprising planarizing the base portion before attaching the lid.

14. The method of claim 9, wherein a thermal conductivity of the base portion is greater than 170 W/mK.

15. A method of manufacturing a semiconductor package, the method comprising:
depositing a first coating portion on a first surface of a base portion to form a carrier substrate, wherein the base portion comprises a first material with a first thermal conductivity greater than 170 W/mK;
bonding the carrier substrate over a first semiconductor die, wherein a first surface of the first coating portion faces the first semiconductor die; and
bonding the first semiconductor die over a package substrate, wherein the first semiconductor die is electrically connected to the package substrate.

16. The method of claim 15, wherein the first material is a polycrystalline semiconductor material or a polycrystalline dielectric material.

17. The method of claim 15, wherein the first coating portion comprises a second material different from the first material, and wherein the second material is a polycrystalline semiconductor material or a polycrystalline dielectric material.

18. The method of claim 15, further comprising planarizing the first surface of the first coating portion before bonding the carrier substrate over the first semiconductor die, wherein an average roughness of the first surface of the first coating portion is smaller than 0.3 nm after planarizing the first surface of the first coating portion.

19. The method of claim 15, further comprising depositing a second coating portion on a second surface of the base portion opposite the first surface, wherein the first coating portion and the second coating portion comprise a same material.

20. The method of claim 19, further comprising planarizing a first surface of the second coating portion, wherein an average roughness of the first surface of the second coating portion is smaller than 10 nm after planarizing the first surface of the second coating portion.
